(19) United States
(12) Patent Application Publication
(10) Pub. No.: US 2026/0082494 A1
(43) Pub. Date: Mar. 19, 2026

(54) WIRELESS MOUSE

(71) Applicant: WAYMEET (SHENZHEN) TECHNOLOGY CO., LTD., Shenzhen (CN)

(72) Inventors: Zhenhua MENG, Shenzhen (CN); Qi LIN, Shenzhen (CN); Weihao HU, Shenzhen (CN)

(73) Assignee: WAYMEET (SHENZHEN) TECHNOLOGY CO., LTD., Shenzhen (CN)

(21) Appl. No.: 19/269,260

(22) Filed: Jul. 15, 2025

(30) Foreign Application Priority Data
Sep. 13, 2024 (CN) 202422254835.1
Jun. 12, 2025 (CN) 202521205171.8

(51) Int. Cl. H05K 5/02; G06F 3/0354; H05K 5/00

(52) U.S. Cl. CPC H05K 5/0247; G06F 3/03543; H05K 5/0086

(57) ABSTRACT

A wireless mouse includes a mouse body and a charging cable. The mouse body is provided with an accommodating chamber and a wire-passing hole, the accommodating chamber is communicated with the outside through the wire-passing hole. The mouse body includes a battery and a circuit board, the battery and the circuit board are provided in the accommodating chamber, and the battery is electrically connected to the circuit board. One end of the charging cable is configured to be electrically connected to a computer. The other end of the charging cable passes through the wire-passing hole and is located in the accommodating chamber, and is electrically connected to the circuit board.

### CROSS-REFERENCE TO RELATED APPLICATIONS

The present application claims priority to Chinese Patent Application No. 202422254835.1, filed on Sep. 13, 2024, and Chinese Patent Application No. 202521205171.8, filed on Jun. 12, 2025, the entire contents of which are incorporated herein by reference.

### TECHNICAL FIELD

The present application relates to the technical field of computer peripheral equipment, in particular to a wireless mouse.

### BACKGROUND

The mouse is one of the accessories of the computer, which is a machine connected to the computer to control the cursor. With the development of the times, the function and structure of the mouse are constantly improving, and wireless mouses have gradually appeared. Wireless mouses usually communicate with computers by wireless communication, thus eliminating the constraints of communication lines, greatly facilitating daily office work and making computer work more flexible.

Existing wireless mouses are usually powered by batteries, which are specifically divided into two power supply modes: dry cell power supply and rechargeable battery power supply. For wireless mouse powered by dry cells, the batteries must be replaced after a period of use. Users need to regularly replace dry cells to ensure the normal operation of the wireless mouse. If there is no spare battery, it will cause inconvenience to use. Dry cells are not environmentally friendly products, and discarded batteries pollute the environment and increase the cost of use. For the method of using rechargeable batteries for power supply, users can connect the mouse to the computer for charging via a charging cable. Users need to carry a charging cable to ensure the normal operation of the wireless mouse. Whether it is a dry cell or a charging cable, it is difficult for users to carry it with them at all times. Both of the above power supply modes make the power supply of the wireless mouse limited to the supply of battery power. When the user cannot confirm when the power of the wireless mouse will be exhausted, if the wireless mouse suddenly runs out of power during office work or meetings, the battery power of the wireless mouse cannot be replenished in time, resulting in interruption of the use of the mouse during the operation of the computer, thereby affecting work efficiency.

### SUMMARY

The embodiment of the present application provides a wireless mouse, which can replenish the battery power of the wireless mouse in time when the battery of the wireless mouse is suddenly exhausted, thereby reducing the impact of office inconvenience caused by insufficient power of the wireless mouse, and improving work efficiency.

The wireless mouse provided in the present application adopts the following technical solution.

A wireless mouse, including:
a mouse body provided with an accommodating chamber and a wire-passing hole; and
a charging cable.

The accommodating chamber is connected to outside through the wire-passing hole; the mouse body includes a battery and a circuit board, the battery and the circuit board are provided in the accommodating chamber, and the battery is electrically connected to the circuit board; one end of the charging cable is configured to be electrically connected to a power supply device, and the other end of the charging cable is configured to pass through the wire-passing hole to be provided in the accommodating chamber and is electrically connected to the circuit board.

In an embodiment, the wireless mouse further includes a wire pressing plate and a connection member provided in the accommodating chamber. The wire pressing plate is provided at one end of the charging cable close to the circuit board, contacts and presses the charging cable to fix the charging cable, and is fixedly connected to the mouse body through the connection member.

In an embodiment, one end of the charging cable connected to the power supply device is provided with a charging interface, the mouse body is provided with a receiving groove, and the receiving groove is configured to store the charging interface.

In an embodiment, the receiving groove is provided at an end surface of the mouse body in contact with a desktop, the charging cable is configured to pass through the wire-passing hole so that the charging interface is assembled in the receiving groove, and the accommodating chamber is configured to store a redundant length of the charging cable.

In an embodiment, the mouse body includes a base and an upper cover detachably connected to the base, and the accommodating chamber is provided at the base; and the accommodating chamber includes an installation region located at a rear end of the base, the installation region is configured to accommodate the battery and the circuit board, and the battery and the circuit board are fixedly installed on the base.

In an embodiment, the accommodating chamber includes a receiving region provided at a front end of the mouse body, and the wire-passing hole is communicated with the receiving region; and the wire-passing hole is provided at the front end of the mouse body, and is formed by enclosing the upper cover and the base.

In an embodiment, the receiving groove is the receiving region, and the charging cable is bent along a peripheral wall of the base so that the charging cable and the charging interface are both provided in the receiving region.

In an embodiment, the upper cover is provided with an installation post and a first magnet, and the first magnet is assembled at the installation post; the base is provided with a support partition and a second magnet, and the second magnet is assembled at the support partition; and the second magnet is provided corresponding to the first magnet, and the upper cover is magnetically connected to the base by the first magnet and the second magnet.

In an embodiment, the charging cable and the circuit board are fixed by welding, or the charging cable and the circuit board are fixed by plugging to achieve electrical connection.

In an embodiment, the charging cable is a flexible cable, and the charging cable is set at a preset length, and the charging interface is bent in response to being assembled with the receiving groove so that the charging interface is provided in the receiving groove.

In an embodiment, the wireless mouse is provided with a first magnetic member provided corresponding to the charging cable, the charging cable is provided with a second magnetic member along a length direction, and the first magnetic member is magnetically connected to the second magnetic member.

In an embodiment, the first magnetic member is provided in the accommodating chamber or in the receiving groove.

In an embodiment, the charging cable includes a wire body, and the wire body is magnetic and is magnetically connected to the first magnetic member.

It can be seen from the above technical solutions that the embodiments of the present application have the following advantages:

When the battery of the wireless mouse is suddenly exhausted, the charging cable that comes with the wireless mouse can be used as an emergency measure. One end of the charging cable is electrically connected to the power supply device, and the battery is charged through the charging cable. The battery power of the wireless mouse can be replenished in time, reducing the impact of office inconvenience caused by insufficient power of the wireless mouse, thereby improving work efficiency.

### BRIEF DESCRIPTION OF THE DRAWINGS

In order to more clearly illustrate the technical solutions in the embodiments of the present application, the drawings required for use in the description of the embodiments will be briefly introduced below. Obviously, the drawings described below are only some embodiments recorded in the present application. For persons skilled in the art, other drawings can also be obtained based on these drawings.

FIG. 1 is an overall structure view of a wireless mouse according to an embodiment of the present application.

FIG. 2 is a structural disassembly view of the wireless mouse according to an embodiment of the present application, showing a base.

FIG. 3 is a schematic structural view of the wireless mouse according to an embodiment of the present application, showing a receiving groove.

FIG. 4 is a structure view of the wireless mouse according to an embodiment of the present application, showing the storage of a charging cable.

FIG. 5 is a structural disassembly view of the wireless mouse according to another embodiment of the present application, showing a base.

FIG. 6 is a structure view of the wireless mouse according to another embodiment of the present application, showing an upper cover.

FIG. 7 is a structure view of the wireless mouse according to another embodiment of the present application, showing the storage of a charging cable.

FIG. 8 is an overall structure view of the wireless mouse according to another embodiment of the present application.

FIG. 9 is a cross-sectional view of the wireless mouse according to another embodiment of the present application.

### DETAILED DESCRIPTION OF THE EMBODIMENTS

The present application is further described in detail below in conjunction with the accompanying drawings.

An embodiment of the present application provides a wireless mouse.

In order to enable persons skilled in the art to better understand the solutions of the present application, the technical solutions in the embodiments of the present application will be clearly and completely described below in conjunction with the drawings in the embodiments of the present application. Obviously, the described embodiments are only embodiments of a part of the present application, not all embodiments. Based on the embodiments of the present application, all other embodiments obtained by persons skilled in the art without creative efforts should fall within the scope of the present application. In addition, the technical solutions between the various embodiments can be combined with each other, but they must be based on the ability of persons skilled in the art to implement them. When the combination of technical solutions is contradictory or cannot be implemented, it should be considered that such a combination of technical solutions does not exist and is not within the scope of the present application.

The terms “first”, “second”, “third”, “fourth”, etc. in the specification and claims of the present application and the above-mentioned drawings are used to distinguish similar objects, and are not necessarily used to describe a specific order or sequence. It should be understood that the data used in this way can be interchanged where appropriate, so that the embodiments described herein can be implemented in an order other than that illustrated or described herein. In addition, the terms “include” and “have” and any variations thereof are intended to cover non-exclusive inclusions. For example, a process, method, system, product or device that includes a series of steps or units is not necessarily limited to those steps or units clearly listed, but may include other steps or units that are not clearly listed or inherent to these processes, methods, products or devices.

Existing wireless mouses are usually powered by batteries, which are specifically divided into two power supply modes: dry cell power supply and rechargeable battery power supply. For wireless mouse powered by dry cells, the batteries must be replaced after a period of use. Users need to regularly replace dry cells to ensure the normal operation of the wireless mouse. If there is no spare battery, it will cause inconvenience to use, and dry cells are not environmentally friendly products. Discarded batteries pollute the environment and increase the cost of use. For the method of using rechargeable batteries for power supply, users can connect the wireless mouse to the computer for charging through a charging cable. Users need to carry a charging cable to ensure the normal operation of the wireless mouse. Whether it is a dry cell or a charging cable, it is difficult for users to carry it with them at all times. Both of the above power supply modes make the power supply of the wireless mouse limited to the supply of battery power. When the user cannot confirm when the power of the wireless mouse will be exhausted, if the wireless mouse suddenly runs out of power during office work or meetings, the battery power of the wireless mouse cannot be replenished in time, resulting in interruption of the use of the mouse during the operation of the computer, thereby affecting work efficiency.

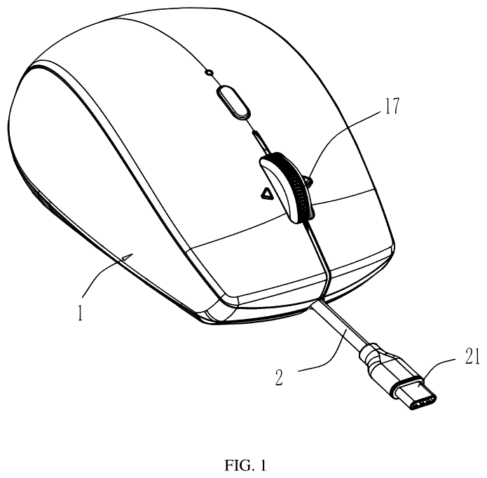

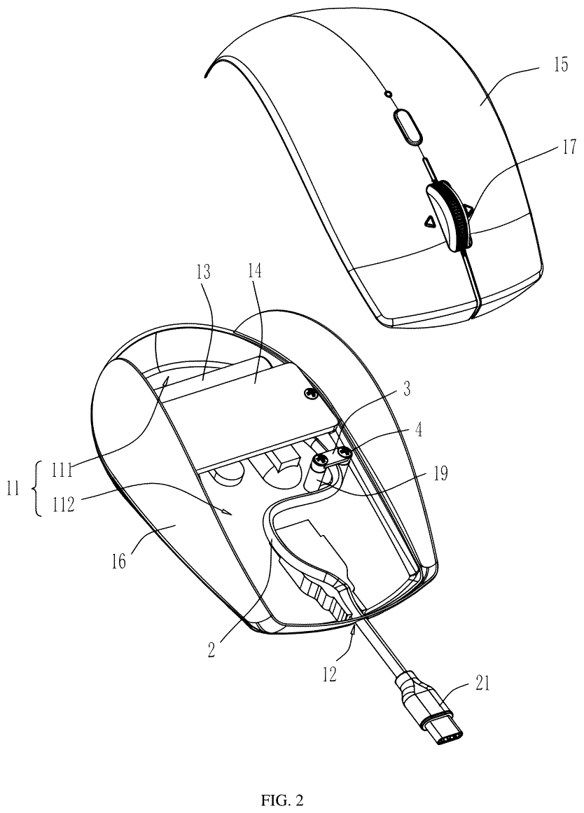

In order to solve the above technical problems, the present application provides a wireless mouse, as shown in FIG. 1 and FIG. 2, which are a specific embodiment of the wireless mouse of the present application. The wireless mouse includes a mouse body 1 and a charging cable 2. The mouse body 1 is provided with an accommodating chamber 11 and a wire-passing hole 12, and the accommodating chamber 11 is communicated with the outside through the wire-passing hole 12. The mouse body 1 includes a battery 13 and a circuit board 14, the battery 13 and the circuit board 14 are provided in the accommodating chamber 11, and the battery 13 is electrically connected to the circuit board 14. One end of the charging cable 2 is used to be electrically connected to the power supply device, and the other end of the charging cable 2 passes through the wire-passing hole 12 and is located in the accommodating chamber 11, and is electrically connected to the circuit board 14 to form a current path to charge the battery 13. It can be understood that the power supply device includes a charger, a mobile power supply device, a computer and other devices that can provide electrical energy. When the power of the wireless mouse is suddenly exhausted, the charging cable 2 can be used for emergency, and one end of the charging cable 2 is electrically connected to the computer. When the charging cable 2 is electrically connected to the computer, the control function of the wired mouse is formed, and the battery 13 is replenished with power at the same time. When one end of the charging cable 2 is electrically connected to other power supply device, the battery 13 can be charged through the charging cable 2, which can replenish the power of the battery 13 of the wireless mouse in time, reduce the impact of office inconvenience caused by insufficient power of the wireless mouse, and thus improve work efficiency.

As shown in FIG. 2, the mouse body 1 includes a base 16, an upper cover 15 and a scroll wheel 17. The base 16 contacts the desktop and is used to provide an installation base for components such as a battery 13 and a circuit board 14. The upper cover 15 is provided with an arc surface that fits the hand structure, so as to facilitate the hand to grasp the mouse body 1 to apply force. In this embodiment, the accommodating chamber 11 is provided at the base 16, the scroll wheel 17 is rotatably provided on the upper cover 15, and part of the scroll wheel 17 is located in the accommodating chamber 11. There is a gap between the lowest point of the scroll wheel 17 and the highest point of the charging cable 2. When the scroll wheel 17 is rolled, there is no interference between the scroll wheel 17 and the charging cable 2, which is conducive to the operation and use of the scroll wheel 17.

The accommodating chamber 11 includes an installation region 111 and a receiving region 112. The installation region 111 is located at the rear end of the base 16 and is configured to accommodate the battery 13 and the circuit board 14. The receiving region 112 is located at the front end of the base 16 and is configured to accommodate part of the charging cable 2. The battery 13 and the circuit board 14 in the installation region 111 are fixedly installed on the base 16. Specifically, the circuit board 14 is located above the battery 13, and the circuit board 14 is fixedly installed on the base 16 by self-tapping screws. In some embodiments, the charging cable 2 and the circuit board 14 are fixed by welding to achieve electrical connection. In some other embodiments, a connector is provided at the end of the charging cable 2 close to the circuit board 14, and the circuit board 14 is provided with a connection interface adapted to the connector. The charging cable 2 and the circuit board 14 are plugged into each other through the connector and the connection interface to achieve electrical connection.

In order to enhance the installation stability of the charging cable 2 and the circuit board 14, the wireless mouse is also provided with a wire pressing plate 3 and a connection member 4, both of which are provided in the accommodating chamber 11. The wire pressing plate 3 is provided at one end of the charging cable 2 close to the circuit board 14, the wire pressing plate 3 contacts and presses the charging cable 2 to fix the charging cable 2, and the wire pressing plate 3 is fixedly connected to the mouse body 1 through the connection member 4. At least two connection members 4 are provided, the wire pressing plate 3 is provided with at least two connection holes, and the connection members 4 correspond to the installation holes one by one. One end of the connection member 4 is pressed against the wire pressing plate 3, and the other end of the connection member 4 passes through an installation hole to be fixedly connected to the mouse body 1. It can be understood that the wire pressing plate 3 is located above the charging cable 2, and the connection member 4 can be a self-tapping screw. The wire pressing plate 3 is locked to the base 16 by passing the connection hole through the connection member 4. In the process of locking the wire pressing plate 3, the wire pressing plate 3 contacts and presses the charging cable 2 to achieve the compression of the charging cable 2, thereby fixing one end of the charging cable 2 close to the circuit board 14 and preventing the charging cable 2 from detaching from the circuit board 14 when the charging cable 2 is pulled. On the other hand, it has the effect of arranging the charging cable 2 to reduce the interference of the charging cable 2 on other components in the accommodating chamber 11.

Furthermore, the base 16 is provided with a support post 19, which is used to raise the height of the end portion of the charging cable 2 connected to the circuit board 14. The support post 19 and the base 16 are integrally formed, and the upper end surface of the support post 19 cooperates with the lower end surface of the wire pressing plate 3 to clamp the charging cable 2, thereby fixing the position of the end portion of the charging cable 2 connected to the circuit board 14, reducing the possibility of poor contact caused by the height difference between the circuit board 14 and the charging cable 2, thereby further improving the stability of the electrical connection between the charging cable 2 and the circuit board 14.

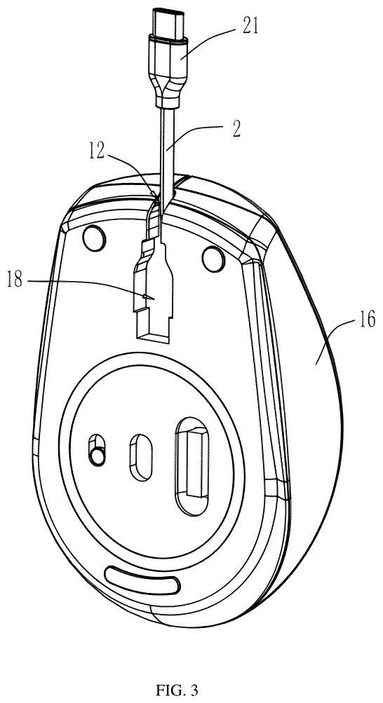

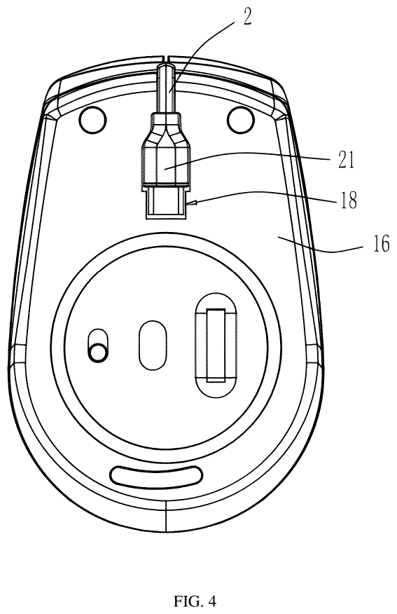

As shown in FIG. 2 to FIG. 4, the end of the charging cable 2 connected to the computer is provided with a charging interface 21 for easy plugging, the mouse body 1 is provided with a receiving groove 18, and the receiving groove 18 is used to store the charging interface 21. The charging cable 2 is a flexible cable, and the charging cable 2 is configured to be set with a preset length. When the charging interface 21 is assembled with the receiving groove 18, the charging cable 2 is bent so that the charging interface 21 is located in the receiving groove 18. It can be understood that the charging cable 2 has sufficient length to ensure that the charging interface 21 can be smoothly plugged into the computer and electrically connected to the computer, and at the same time, it can also ensure that the charging cable 2 has sufficient length so that the charging interface 21 reaches the receiving groove 18. The flexible property enables the charging cable 2 to be bent to adapt to the setting direction of the receiving groove 18 during the storage process of the charging interface 21.

In this embodiment, the wire-passing hole 12 is provided at the front end of the base 16, the wire-passing hole 12 is formed by opening a through hole in the base 16, and the wire-passing hole 12 is communicated with the receiving region 112. The receiving groove 18 is provided at the end surface of the base 16 which is in contact with the desktop, and the charging cable 2 is passed through the wire-passing hole 12 so that the charging interface 21 is assembled in the receiving groove 18, and the receiving region 112 is used to store the redundant length of the charging cable 2. The receiving groove 18 is arranged near the front end of the base 16, and the central axis of the receiving groove 18 and the central axis of the wire-passing hole 12 are both located on the central axis surface of the base 16. The receiving region 112 is communicated with the receiving groove 18 through the wire-passing hole 12, and the charging cable 2 is passed through the wire-passing hole 12 so that the charging interface 21 is assembled in the receiving groove 18. The receiving groove 18 is used to store the charging interface 21 and part of the charging cable 2 connected to the charging interface 21. This setting method is intended to achieve the storage of the charging interface 21 and the charging cable 2 in the shortest path.

When the battery 13 is insufficient and needs to be supplemented with electricity, the charging interface 21 is plugged into the power supply device to charge the battery 13 through the charging cable 2. After charging is completed, in the process of storing the charging cable 2, one end of the charging cable 2 connected to the charging interface 21 is bent toward the end surface of the base 16 that is in contact with the desktop, so that the charging interface 21 gradually approaches the receiving groove 18, thereby storing the charging interface 21 in the receiving groove 18. The remaining part of the charging cable 2 enters the receiving region 112 through the wire-passing hole 12, and the receiving region 112 is used to store the redundant length of the charging cable 2.

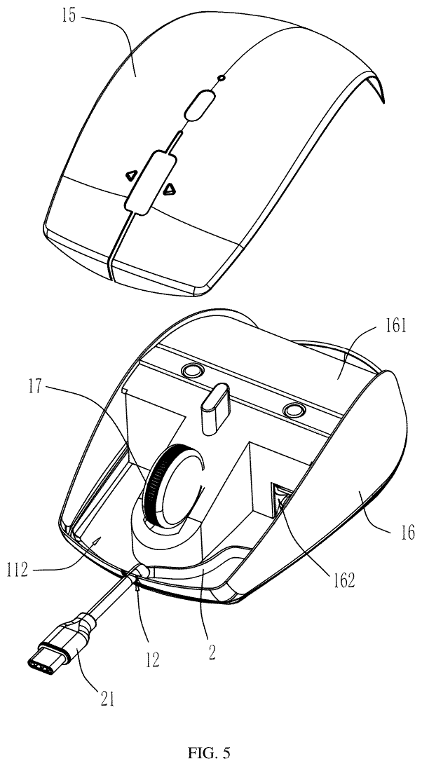

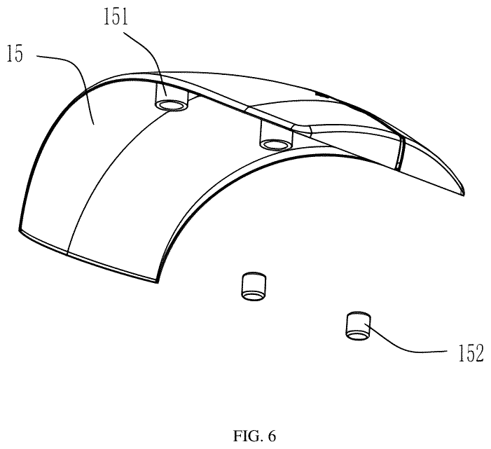

As shown in FIG. 5 and FIG. 6, in an embodiment, the upper cover 15 is detachably connected to the base 16, which allows the user to easily disassemble the mouse body 1 and more conveniently store and assemble the charging cable 2. Secondly, it can clean the dust and dirt inside and outside, ensuring the hygiene and maintenance of the wireless mouse. In this embodiment, the upper cover 15 is detachably connected to the base 16 by magnetic attraction. Specifically, the upper cover 15 is provided with an installation post 151 and a first magnet 152, and the first magnet 152 is assembled on the installation post 151. The base 16 is provided with a support partition 161 and a second magnet 163, and the second magnet 163 is assembled on the support partition 161. The second magnet 163 is arranged corresponding to the first magnet 152. The upper cover 15 and the base 16 are magnetically connected by the first magnet 152 and the second magnet 163. The upper cover 15 and the installation post 151 are integrally formed, and a first installation slot is opened in the installation post 151 to accommodate the first magnet 152, and the first magnet 152 is fixedly installed on the upper cover 15 through the first installation slot. The end surface of the support partition 161 close to the upper cover 15 is adapted to the curvature of the upper cover 15 The support partition 161 is opened with a second installation slot corresponding to the first magnet 152, a second magnet 163 is installed in the second installation slot, and the second magnet 163 is fixedly installed on the base 16 through the second installation slot. The first magnet 152 and the second magnet 163 are magnetically attracted to each other, making the upper cover 15 and the base 16 be detachably connected.

In this embodiment, the scroll wheel 17 is rotatably installed on the support partition 161, and the upper cover 15 is provided with an avoidance slot corresponding to the scroll wheel 17. The upper cover 15 is assembled on the base 16, and the scroll wheel 17 is partially passed through the avoidance slot. When the scroll wheel 17 is rolled, there is no interference between the scroll wheel 17, the upper cover 15 and the charging cable 2, which is conducive to the operation and use of the scroll wheel 17.

The support partition 161 separates the installation region 111 from the receiving region 112. The support partition 161 is provided with a connecting hole 162. The connecting hole 162 is used for the charging cable 2 to enter the installation region 111 and be electrically connected to the circuit board 14. That is, the end of the charging cable 2 that is not connected to the charging interface 21 is passed through the connecting hole 162 and is electrically connected to the circuit board 14.

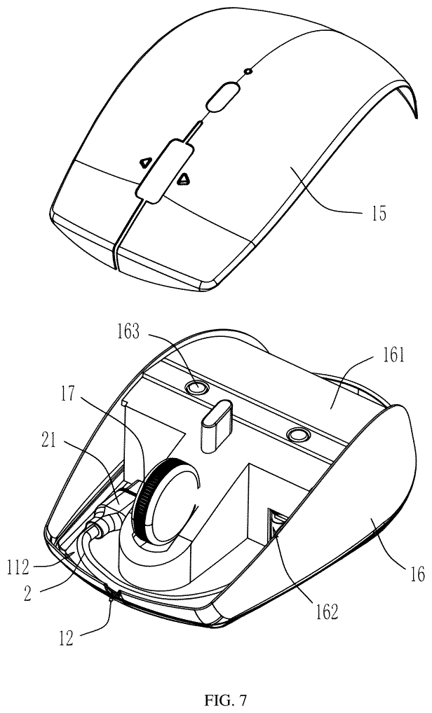

As shown in FIG. 5 and FIG. 7, the wire-passing hole 12 is provided at the front end of the mouse body 1, and the wire-passing hole 12 is formed by enclosing the upper cover 15 and the base 16. It can be understood that the base 16 is provided with a wire-passing slot, and the upper cover 15 and the base 16 are in an assembled state, and the upper cover 15 closes the opening of the wire-passing slot, so that the wire-passing slot forms the wire-passing hole 12. The upper cover 15 and the base 16 are in a disassembled state, and the upper cover 15 releases the closure of the opening of the wire-passing slot, so that the charging cable 2 can be taken out of the wire-passing slot, or the charging cable 2 can be placed in the wire-passing slot.

In this embodiment, the receiving groove 18 is the receiving region 112, that is, the charging interface 21 and the charging cable 2 are both located in the receiving region 112 for storage. It can be understood that based on the length of the charging cable 2, the charging cable 2 is bent along the peripheral wall of the base 16 so that the charging cable 2 and the charging interface 21 are both located in the receiving groove 18.

When the battery 13 is insufficient and needs to be supplemented, the upper cover 15 is removed from the base 16, and the upper cover 15 releases the closure of the wire-passing slot opening. The charging interface 21 is taken out from the receiving region 112 to place the charging cable 2 in the wire-passing slot, and then the upper cover 15 is assembled to the base 16, the charging interface 21 is plugged into the computer, and the battery 13 is charged through the charging cable 2. After charging is completed, in the process of storing the charging cable 2, the charging cable 2 is taken out from the wire-passing slot, and the charging cable 2 is bent along the peripheral wall of the base 16 so that the charging interface 21 gradually approaches the receiving region 112, so that the charging cable 2 and the charging interface 21 are completely stored in the receiving region 112.

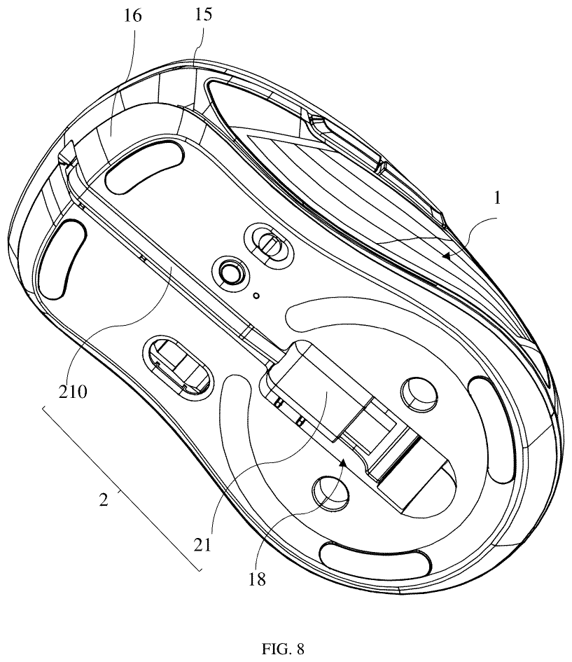

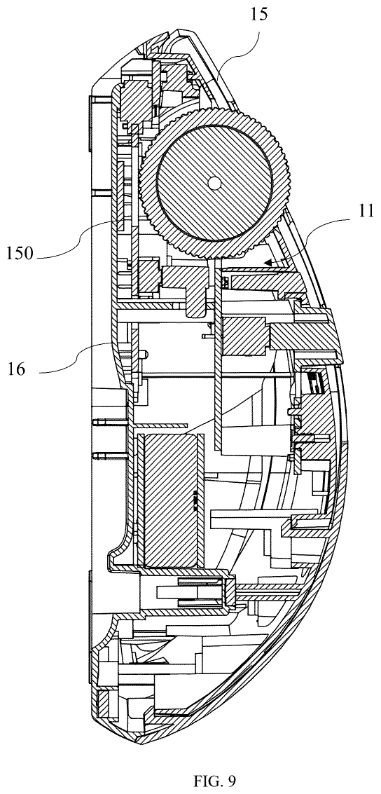

As shown in FIG. 8 and FIG. 9, in an embodiment, the mouse body 1 is provided with a first magnetic member 150. The first magnetic member 150 is provided corresponding to the charging cable 2. The charging cable 2 is provided with a second magnetic member 24 (not shown in the figure) along the length direction. The first magnetic member 150 is magnetically connected with the second magnetic member 24. The first magnetic member 150 is provided in the accommodating chamber 11 or in the receiving groove 18. When the first magnetic member 150 is provided in the accommodating chamber 11, the first magnetic member 150 is fixedly provided on the upper end surface of the base 16, and the first magnetic member 150 and the charging cable 2 are respectively located on both sides of the base 16. When the first magnetic member 150 is arranged in the receiving groove 18, the first magnetic member 150 is fixedly provided on the lower end surface of the base 16, and the first magnetic member 150 and the charging cable 2 are directly attached, shortening the distance between the first magnetic member 150 and the second magnetic member 24, and enhancing the installation stability between the first magnetic member 150 and the second magnetic member 24. It can be understood that the charging cable 2 can be attached to or separated from the receiving groove 18 through the first magnetic member 150 and the second magnetic member 24. When the first magnetic member 150 is magnetically connected to the second magnetic member 24, the charging cable 2 can be tightly attached to the bottom wall of the receiving groove 18, maintaining a certain gap between the charging cable 2 and the desktop, thereby avoiding wear on the charging cable 2 when the mouse body 1 is in use. Secondly, the charging cable 2 is stored in the receiving groove 18, which can keep the desktop tidy and improve the comfort of the office environment. When the magnetic attraction between the first magnetic member 150 and the second magnetic member 24 is released, the charging cable 2 can be taken out of the receiving groove 18 to achieve a wired connection between the charging cable 2 and the computer host.

In an embodiment, the charging cable 2 includes a wire body 210, and the wire body 210 of the charging cable 2 is configured as a magnetic wire body 210. The wire body 210 is magnetically connected to the first magnetic member 150. Integrating the second magnetic member with the wire body 210 can reduce the overall volume of the wire body 210, and correspondingly reduce the depth of the receiving groove 18, so that the size of the mouse body 1 is reduced.

As described above, the above embodiments are only used to illustrate the technical solutions of the present application, rather than to limit the same. Although the present application has been described in detail with reference to the aforementioned embodiments, persons skilled in the art should understand that the technical solutions described in the aforementioned embodiments may still be modified, or some of the technical features thereof may be replaced by equivalents. However, these modifications or replacements do not deviate the essence of the corresponding technical solutions from the spirit and scope of the technical solutions of the embodiments of the present application.

What is claimed is:

1. A wireless mouse, comprising:
a mouse body provided with an accommodating chamber and a wire-passing hole; and
a charging cable,
wherein the accommodating chamber is connected to outside through the wire-passing hole;
the mouse body comprises a battery and a circuit board, the battery and the circuit board are provided in the accommodating chamber, and the battery is electrically connected to the circuit board; and
one end of the charging cable is configured to be electrically connected to a power supply device, and the other end of the charging cable is configured to pass through the wire-passing hole to be provided in the accommodating chamber and is electrically connected to the circuit board.

2. The wireless mouse according to claim 1, further comprising a wire pressing plate and a connection member provided in the accommodating chamber;
wherein the wire pressing plate is provided at one end of the charging cable close to the circuit board, contacts and presses the charging cable to fix the charging cable, and is fixedly connected to the mouse body through the connection member.

3. The wireless mouse according to claim 1, wherein one end of the charging cable connected to the power supply device is provided with a charging interface, the mouse body is provided with a receiving groove, and the receiving groove is configured to store the charging interface.

4. The wireless mouse according to claim 3, wherein the receiving groove is provided at an end surface of the mouse body in contact with a desktop, the charging cable is configured to pass through the wire-passing hole so that the charging interface is assembled in the receiving groove, and the accommodating chamber is configured to store a redundant length of the charging cable.

5. The wireless mouse according to claim 3, wherein the mouse body comprises a base and an upper cover detachably connected to the base, and the accommodating chamber is provided at the base; and
the accommodating chamber comprises an installation region located at a rear end of the base, the installation region is configured to accommodate the battery and the circuit board, and the battery and the circuit board are fixedly installed on the base.

6. The wireless mouse according to claim 5, wherein the accommodating chamber comprises a receiving region provided at a front end of the mouse body, and the wire-passing hole is communicated with the receiving region; and
the wire-passing hole is provided at the front end of the mouse body, and is formed by enclosing the upper cover and the base.

7. The wireless mouse according to claim 6, wherein the receiving groove is the receiving region, and the charging cable is bent along a peripheral wall of the base so that the charging cable and the charging interface are both provided in the receiving region.

8. The wireless mouse according to claim 5, wherein the upper cover is provided with an installation post and a first magnet, and the first magnet is assembled at the installation post;
the base is provided with a support partition and a second magnet, and the second magnet is assembled at the support partition; and
the second magnet is provided corresponding to the first magnet, and the upper cover is magnetically connected to the base through the first magnet and the second magnet.

9. The wireless mouse according to claim 1, wherein the charging cable and the circuit board are fixed by welding, or the charging cable and the circuit board are fixed by plugging to achieve electrical connection.

10. The wireless mouse according to claim 3, wherein the charging cable is a flexible cable, and the charging cable is set at a preset length, and the charging interface is bent when assembled with the receiving groove so that the charging interface is provided in the receiving groove.

11. The wireless mouse according to claim 3, wherein the wireless mouse is provided with a first magnetic member corresponding to the charging cable, the charging cable is provided with a second magnetic member along a length direction of the charging cable, and the first magnetic member is magnetically connected to the second magnetic member.

12. The wireless mouse according to claim 11, wherein the first magnetic member is provided in the accommodating chamber or in the receiving groove.

13. The wireless mouse according to claim 11, wherein the charging cable comprises a wire body, and the wire body is magnetic and is magnetically connected to the first magnetic member.
